(19) United States
(12) Patent Application Publication
(10) Pub. No.: US 2025/0024691 A1
(43) Pub. Date: Jan. 16, 2025

(54) THREE-DIMENSIONAL MEMORY DEVICE AND METHOD OF FABRICATING THE SAME

(71) Applicant: SAMSUNG ELECTRONICS CO., LTD., Suwon-si (KR)

(72) Inventors: Youngsun SONG, Suwon-si (KR); Seulji Song, Suwon-si (KR); Bon Jae Koo, Suwon-si (KR)

(21) Appl. No.: 18/417,937

(22) Filed: Jan. 19, 2024

(30) Foreign Application Priority Data
Jul. 11, 2023 (KR) 10-2023-0090071
Aug. 16, 2023 (KR) 10-2023-0107226

(51) Int. Cl. H10B 99/00

(52) U.S. Cl. CPC H10B 99/10

(57) ABSTRACT

A three-dimensional memory device includes a base dielectric layer disposed on a substrate, a stack structure that includes word lines and interlayer dielectric layers that are alternately stacked on the base dielectric layer, a bit line that penetrates the stack structure and extends in a vertical direction perpendicular to a top surface of the substrate, and buried storage patterns interposed between the bit line and the word lines and spaced apart from each other in the vertical direction. Each of the buried storage patterns has a width in a horizontal direction parallel to the top surface of the substrate. The widths of the buried storage patterns increase with increasing vertical distance from the substrate.

### CROSS-REFERENCE TO RELATED APPLICATIONS

This U.S. nonprovisional application claims priority under 35 U.S.C. § 119 from Korean Patent Applications No. 10-2023-0090071, filed on Jul. 11, 2023, and No. 10-2023-0107226, filed on Aug. 16, 2023 in the Korean Intellectual Property Office, the contents of both which are herein incorporated by reference in their entireties.

### TECHNICAL FIELD

The present inventive concepts relate to a three-dimensional memory device and a method of fabricating the same.

### DISCUSSION OF THE RELATED ART

An existing resistive memory device, such as an RRAM, a PRAM, and an MRAM, has a memory material that remembers the resistance state and, a discrete switch, such as a transistor, a diode, or a threshold switch, but an Ovonic threshold switch (OTS)-only memory, such as a selector only memory device that includes a chalcogenide-based single material, exhibits both memory and selector characteristics and has increased integration due to a simplified structure in which upper and lower electrodes and an SOM material are stacked. However, for a two-dimensional cell array structure, an increase in cell array size leads to an increase in leakage current, and thus a three-dimensional vertical cross-point memory structure has recently been suggested.

### SUMMARY

Some embodiments of the present inventive concepts provide a three-dimensional memory device with increased reliability and operating speed variation due to a thickness change of storage patterns between upper and lower cells.

Some embodiments of the present inventive concepts provide a method of fabricating a three-dimensional memory device.

According to some embodiments of the present inventive concepts, a three-dimensional memory device includes: a base dielectric layer disposed on a substrate; a stack structure that includes a plurality of word lines and a plurality of interlayer dielectric layers that are alternately stacked on the base dielectric layer; a bit line that penetrates the stack structure and extends in a vertical direction perpendicular to a top surface of the substrate; and a plurality of buried storage patterns interposed between the bit line and the word lines and spaced apart from each other in the vertical direction, where the buried storage patterns surround a lateral surface of the bit line. Each of the buried storage patterns has a width in a horizontal direction parallel to the top surface of the substrate. The widths of the buried storage patterns increase with increasing vertical distance from the substrate.

According to some embodiments of the present inventive concepts, a three-dimensional memory device includes: a base dielectric layer disposed on a substrate; a stack structure that includes a plurality of word lines and a plurality of interlayer dielectric layers that are alternately stacked on the base dielectric layer; a bit line that penetrates the stack structure and extends in a vertical direction perpendicular to a top surface of the substrate; and a line storage pattern that extends in the vertical direction between the bit line and the stack structure and surrounds a lateral surface of the bit line. The line storage pattern has a width in a horizontal direction parallel to the top surface of the substrate. The width of the line storage pattern increases with increasing vertical distance from the substrate.

According to some embodiments of the present inventive concepts, a three-dimensional memory device includes: a substrate that includes a cell array region and a contact region that extends from the cell array region; a stack structure that includes a plurality of interlayer dielectric layers and a plurality of word lines that are alternately stacked on the substrate, where the stack structure includes a plurality of pad portions that have a stepwise structure on the contact region; a pad dielectric layer that covers the pad portions of the stack structure on the contact region; a plurality of bit lines that penetrate the stack structure on the cell array region and extend in a vertical direction perpendicular to a top surface of the substrate; a plurality of buried storage patterns interposed between the word lines and each of the bit lines and spaced apart from each other in the vertical direction, where the buried storage patterns surround a lateral surface of each of the bit lines; an upper dielectric layer that covers the stack structure; and a plurality of cell contact plugs that penetrate the upper dielectric layer and the pad dielectric layer on the contact region and are connected to the word lines. The word lines have lengths in a first direction parallel to the top surface of the substrate. The lengths decrease with increasing vertical distance from the top surface of the substrate. Each of the buried storage patterns have a width in a horizontal direction parallel to the top surface of the substrate. The widths of the buried storage patterns increase with increasing vertical distance from the substrate.

According to some embodiments of the present inventive concepts, a three-dimensional memory device includes: a substrate that includes a cell array region and a contact region that extends from the cell array region; a stack structure that includes a plurality of interlayer dielectric layers and a plurality of word lines that are alternately stacked on the substrate, where the stack structure includes a plurality of pad portions that have a stepwise structure on the contact region; a pad dielectric layer that covers the pad portions of the stack structure on the contact region; a plurality of bit lines that penetrate the stack structure on the cell array region and extend in a vertical direction perpendicular to a top surface of the substrate; a plurality of line storage patterns that extend in the vertical direction between the stack structure and each of the bit lines and surround a lateral surface of each of the bit lines; an upper dielectric layer that covers the stack structure; and a plurality of cell contact plugs that penetrate the upper dielectric layer and the pad dielectric layer on the contact region and are connected to the word lines. The word lines may have lengths in a first direction parallel to the top surface of the substrate. The lengths decrease with increasing vertical distance from the top surface of the substrate. The line storage patterns have widths in a horizontal direction parallel to the top surface of the substrate. The widths of the line storage patterns increase with increasing vertical distance from the substrate.

### BRIEF DESCRIPTION OF DRAWINGS

FIG. 1 is a plan view of a three-dimensional memory device according to some embodiments of the present inventive concepts.

FIG. 2 is a cross-sectional view taken along line I-I′ of FIG. 1 that shows a three-dimensional memory device according to some embodiments of the present inventive concepts.

FIG. 3 is an enlarged view of section A of FIG. 2.

FIGS. 4 to 8 are cross-sectional views that illustrate a method of fabricating a three-dimensional memory device of FIGS. 2 and 3.

FIG. 9 is a cross-sectional view of a three-dimensional memory device according to some embodiments of the present inventive concepts.

FIGS. 10A to 10C are cross-sectional views that illustrate a method of fabricating a three-dimensional memory device of FIG. 9.

FIG. 11 is a cross-sectional view of a three-dimensional memory device according to some embodiments of the present inventive concepts.

FIGS. 12A and 12B are cross-sectional views that illustrate a method of fabricating a three-dimensional memory device of FIG. 11.

FIG. 13 is a cross-sectional view of a three-dimensional memory device according to some embodiments of the present inventive concepts.

FIGS. 14A and 14B are cross-sectional views that illustrate a method of fabricating a three-dimensional memory device of FIG. 13.

FIGS. 15 and 16 are cross-sectional views of a three-dimensional memory device according to some embodiments of the present inventive concepts.

FIG. 17A is a plan view of a three-dimensional memory device according to some embodiments of the present inventive concepts.

FIG. 17B is a cross-sectional view taken along line I-I′ of FIG. 17A that shows a three-dimensional memory device according to some embodiments of the present inventive concepts.

FIG. 18 is an enlarged view of section B of FIG. 17B.

FIGS. 19 to 21 are cross-sectional views that illustrate a method of fabricating a three-dimensional memory device of FIG. 18.

FIGS. 22 and 23 are cross-sectional views of a three-dimensional memory device according to some embodiments of the present inventive concepts.

### DETAILED DESCRIPTION

The following will now describe in detail some embodiments of the present inventive concepts with reference to the accompanying drawings.

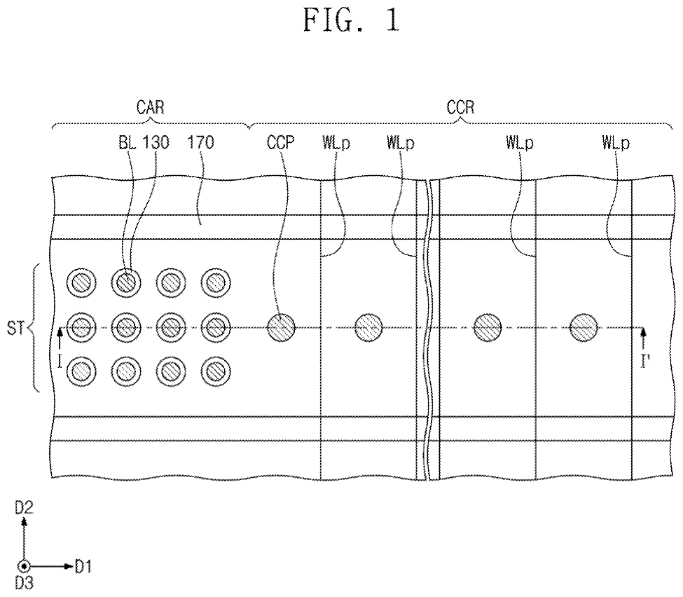

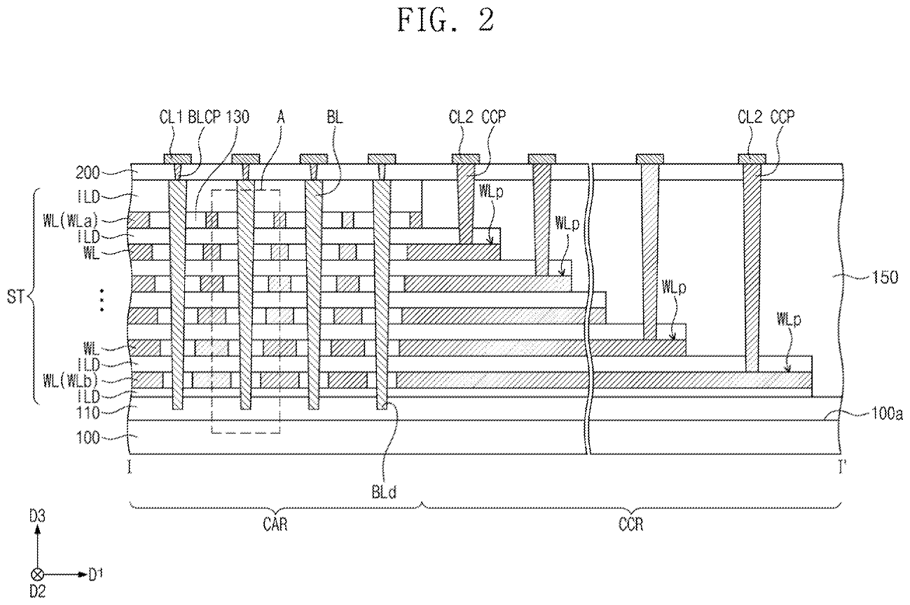

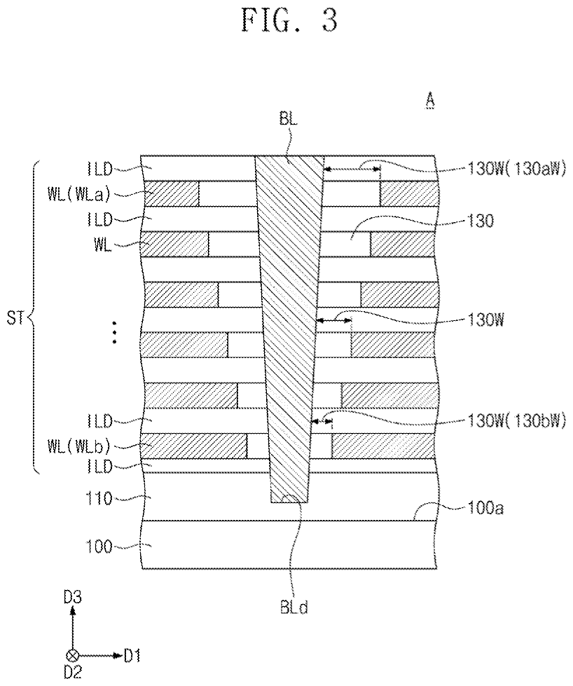

FIG. 1 is a plan view of a three-dimensional memory device according to some embodiments of the present inventive concepts. FIG. 2 is a cross-sectional view taken along line I-I′ of FIG. 1 that shows a three-dimensional memory device according to some embodiments of the present inventive concepts. FIG. 3 is an enlarged view of section A of FIG. 2.

Referring to FIGS. 1 to 3, in an embodiment, a substrate 100 includes a cell array region CAR and a contact region CCR. The substrate 100 extends in a first direction D1 that extends from the cell array region CAR toward the contact region CCR and in a second direction D2 that crosses the first direction D1. A third direction D3 is perpendicular to a top surface 100a of the substrate 100 and intersects the first direction D1 and the second direction D2. For example, the first, second, and third directions D1, D2, and D3 are orthogonal to each other. The third direction D3 may be called a vertical direction, and the first and second directions D1 and D2 may be called horizontal directions. The substrate 100 is a semiconductor substrate that includes at least one of silicon (Si), silicon on insulator (SOI), silicon-germanium (SiGe), germanium (Ge), or gallium-arsenic (GaAs).

When viewed in a plan view, the contact region CCR extends in the first direction D1, or a direction opposite to the first direction D1, from the cell array region CAR. The contact region CCR has a stepwise structure that includes pads portions WLp that will be discussed below.

A base dielectric layer 110 is disposed on the substrate 100. A stack structure ST is disposed on the base dielectric layer 110. The stack structure ST extends in the first direction D1 from the cell array region CAR toward the contact region CCR. A plurality of stack structures ST are provided, and the plurality of stack structures ST are arranged along the second direction D2 and spaced apart from each other in the second direction D2 by a separation structure 170 that will be discussed below. For convenience of description, the following will focus on a single stack structure ST, but this description is also applicable to other stack structures ST.

The stack structure ST may include word lines WL and interlayer dielectric layers ILD that are alternately stacked on the base dielectric layer 110.

The word lines WL have lengths in the first direction D1 that decrease with increasing distance in the third direction D3 from the top surface 100a of the substrate 100. For example, a length in the first direction D1 each word line WL m is greater than a length in the first direction D1 of an immediately overlying word line WL. A lowermost word line WLb has a maximum length in the first direction D1, and an uppermost word lines WLa has a minimum length in the first direction D1.

The word lines WL have pad portions WLp on the contact region CCR. The pad portions WLp of the word lines WL are disposed at positions that horizontally and vertically differ from each other. The pad portions WLp form a stepwise structure along the first direction D1.

The interlayer dielectric layers ILD are interposed between the word lines WL, and have sidewall aligned with those of word lines WL in contact therewith. For example, like the word lines WL, the interlayer dielectric layers ILD have lengths in the first direction D1 that decrease with increasing vertical distance from the top surface 100a of the substrate 100, where a vertical distance is a distance in the vertical direction D3.

The base dielectric layer 110 and the interlayer dielectric layers ILD include, for example, one or more of silicon oxide, silicon nitride, silicon oxynitride, or a low-k dielectric material. For example, the base dielectric layer 110 and the interlayer dielectric layers ILD may include a high-density plasma (HDP) oxide or tetraethylorthosilicate (TEOS).

On the cell array region CAR, bit lines BL are disposed that penetrate the stack structure ST in the third direction D3. The bit lines BL penetrate at least a portion of the base dielectric layer 110. The bit lines BL have bottom surfaces BLd that are positioned in the base dielectric layer 110 but are not in contact with the substrate 100. The bit lines BL are spaced apart from each other in the first direction D1 and the second direction D2. A width of the bit lines BL increases in the first direction D1 or the second direction D2 with increasing distance in the vertical direction D3 from the substrate 100, and extend in the vertical direction D3. Top surfaces of the bit lines BL are substantially coplanar with that of the stack structure ST.

When viewed in a plan view as shown in FIG. 1, the bit lines BL are arranged along the first direction D1 or the second direction D2. The bit lines BL are not disposed in the contact region CCR.

An integrated circuit is disposed between the substrate 100 and the bit lines BL. For example, one or more stacked circuit layers can be disposed on the base dielectric layer 110, and the bit lines BL are electrically connected to the circuit layers. The circuit layers constitute a peripheral circuit that drive memory cells, which will be discussed below.

The word lines WL and the bit lines BL include, for example, at least one of a doped semiconductor, such as doped silicon, a metal, such as tungsten, copper, or aluminum, a conductive metal nitride, such as titanium nitride or tantalum nitride, or a transition metal, such as titanium or tantalum. The word lines WL and the bit lines BL include, for example, tungsten (W).

Buried storage patterns 130 are interposed between the word lines WL and the bit lines BL. The buried storage patterns 130 surround lateral surfaces of the bit lines BL, and are spaced apart from each other in the vertical direction D3. When viewed in a plan view, each of the buried storage pattern 130 has an annular shape that surrounds the lateral surface of the bit line BL. The buried storage patterns 130 are electrically connected to the bit lines BL. The word lines WL are correspondingly connected to the buried storage patterns 130. The buried storage patterns 130 constitute a plurality of memory cells that are stacked in the vertical direction D3.

Each of the buried storage patterns 130 has a width 130W in the horizontal direction, such as the first direction D1 or the second direction D2. At least some of the widths 130W of the buried storage patterns 130 differ from each other. For example, the widths 130W of the buried storage patterns 130 increase with increasing vertical distance from the substrate 100. According to some embodiments, a width 130aW of an uppermost buried storage pattern 130 is greater than a width 130bW of a lowermost buried storage pattern 130.

In comparison with a structure that includes a line storage pattern, a three-dimensional memory device that includes the buried storage patterns 130 has increased reliability. In a three-dimensional memory device that includes a line storage pattern, a material in a storage pattern can diffuse into adjacent cells when a memory cell operates. In contrast, in a structure that includes the buried storage patterns 130, the buried storage patterns 130 are spaced apart in the vertical direction D3 to prevent a material in the buried storage patterns 130 from diffusing to adjacent cells. Accordingly, a three-dimensional memory device has increased reliability and electrical properties.

In a three-dimensional memory device, the word line has a two-dimensional plane shape. Such structural features can lead to the occurrence of parasitic capacitance. A large parasitic capacitance can an increase the time for raising a voltage of the word line WL to an operating voltage (Vth). Therefore, a device has a reduced operating speed. In addition, when the word lines WL have a stepwise structure at the pad portions WLp, a planar area of the word line WL at lower locations is greater than that of the word line WL at upper locations. Therefore, a large parasitic capacitance can be produced at lower locations as compared to upper locations, and the device operating speed may be reduced at lower locations. The difference in operating speed between stacked memory cells can cause a variation of operating characteristics of the memory cells.

According to embodiments of the present inventive concepts, the buried storage patterns 130 have different widths 130W in the vertical direction D3, and reduce variations of operating characteristics between positions of the plurality of memory cells. The buried storage patterns 130 at lower locations intentionally have widths less than those at upper locations, and thus there is a reduction in operating voltage (Vth) at lower locations. Therefore, a reduction in operating speed caused by a large parasitic capacitance at lower locations can be suppressed and a variation in operating characteristics between positions of the plurality of memory cells can be reduced. Accordingly, a three-dimensional memory device has increased reliability.

The buried storage patterns 130 include an Ovonic threshold switch (OTS) material, such as a chalcogenide-based material. For example, the buried storage patterns 130 include at least one of selenium (Se), tellurium (Te), arsenic (As), antimony (Sb), carbon (C), germanium (Ge), silicon (Si), or indium (In).

On the contact region CCR, a pad dielectric layer 150 is disposed that cover the stack structure ST and a portion of the base dielectric layer 110. For example, the pad dielectric layer 150 is disposed on the pad portions WLp of the word lines WL and covers a stepwise structure of the stack structure ST. The pad dielectric layer 150 has a top surface substantially coplanar with that of the stack structure ST.

The pad dielectric layer 150 may include one dielectric layer or a plurality of stacked dielectric layers. The dielectric layer includes one or more of silicon oxide, silicon nitride, silicon oxynitride, or a low-k dielectric material. The pad dielectric layer 150 includes a dielectric material that differs from that of the interlayer dielectric layer ILD of the stack structure ST. For example, when the interlayer dielectric layers ILD of the stack structure ST include a high-density plasma oxide, the pad dielectric layer 150 includes tetraethylorthosilicate (TEOS).

An upper dielectric layer 200 is disposed on the pad dielectric layer 150 and the stack structure ST. The upper dielectric layer 200 includes, for example, one or more of silicon oxide, silicon nitride, silicon oxynitride, or a low-k dielectric material. For example, the upper dielectric layer 200 includes a dielectric material substantially the same as that of the pad dielectric layer 150 and different from that of the interlayer dielectric layers ILD of the stack structure ST.

On the cell array region CAR, bit-line contact plugs BLCP are disposed that penetrate the upper dielectric layer 200 and connect with the bit lines BL. On the contact region CCR, cell contact plugs CCP are disposed that penetrate the upper dielectric layer 200 and the pad dielectric layer 150 and connect with the word lines WL. Each of the cell contact plugs CCP penetrates one of the interlayer dielectric layers ILD and comes into direct contact with one of the pad portions WLp of the word lines WL. The cell contact plugs CCP are spaced apart from each other in the first direction D1.

First conductive lines CL1 are disposed on the upper dielectric layer 200 in the cell array region CAR and are correspondingly connected to the bit-line contact plugs BLCP. Second conductive lines CL2 are disposed on the upper dielectric layer 200 in the contact region CCR and are correspondingly connected to the cell contact plugs CCP.

The bit-line contact plugs BLCP, the cell contact plugs CCP, and the first and second conductive lines CL1 and CL2 include a conductive material, such as a metal. In addition, additional lines and additional vias are disposed on the upper dielectric layer 200 and are electrically connected to the first and second conductive lines CL1 and CL2.

When a plurality of the stack structures ST are provided, a separation structure 170 is provided that extends in the first direction D1 between the plurality of stack structures ST. A plurality of separation structure 170 are provided, and the plurality of separation structures 170 are spaced apart from each other in the second direction D2.

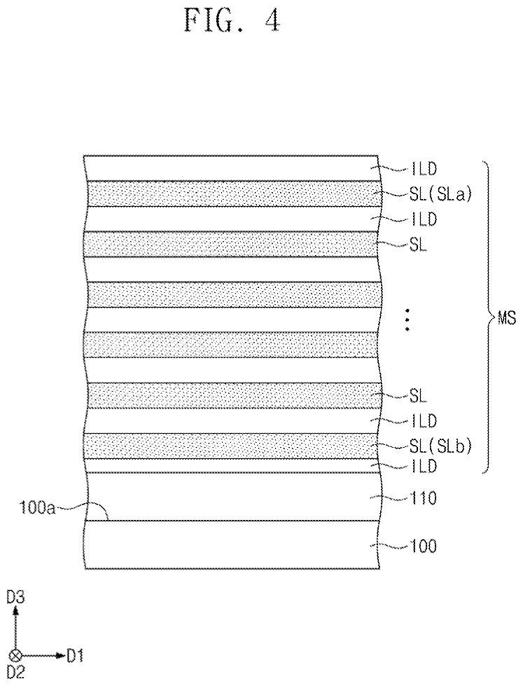

FIGS. 4 to 8 are cross-sectional views that illustrate a method of fabricating a three-dimensional memory device of FIGS. 2 and 3.

For convenience of description, the following will describe a single stack structure ST and a single bit line BL, and this description will also be applicable to other bit lines BL that penetrate other stack structures ST.

Referring to FIG. 4, in an embodiment, a base dielectric layer 110 is formed on a substrate 100. Sacrificial layers SL and interlayer dielectric layers ILD are alternately stacked and form a mold structure MS on the base dielectric layer 110. The sacrificial layers SL have an etch selectivity with respect to the base dielectric layer 110 and the interlayer dielectric layers ILD. For example, the sacrificial layers SL are formed of silicon nitride, and the interlayer dielectric layers ILD are formed of silicon oxide.

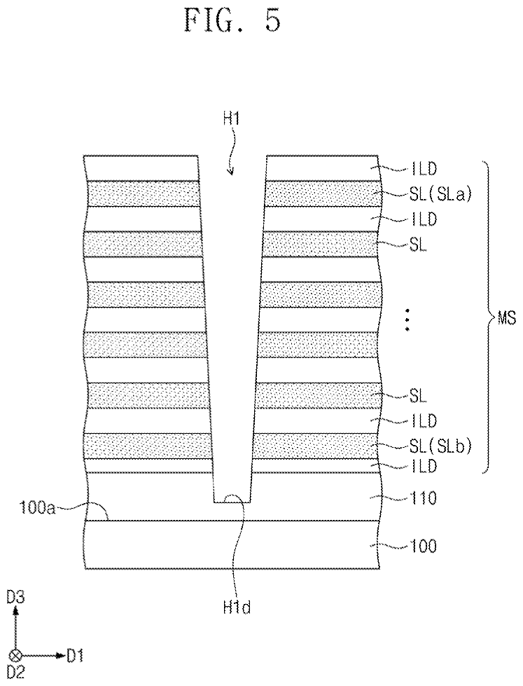

Referring to FIG. 5, in an embodiment, a first hole H1 is formed that penetrates the mold structure MS and a portion of the base dielectric layer 110 in the third direction D3. The first hole H1 has a width in a horizontal direction, such as a first direction D1 or a second direction D2, that increases with increasing vertical distance from the substrate 100. A plurality of first holes H1 are formed that are spaced apart from each other in the first direction D1. The first hole H1 has a bottom surface H1d positioned in the base dielectric layer 110. For example, the first hole H1 penetrates an upper portion of the base dielectric layer 110, but does not expose a top surface 100a of the substrate 100. An anisotropic etching process is performed to form the first hole H1.

Before the formation of the first hole H1, a trimming process is performed on the mold structure MS in a contact region (see CCR of FIG. 1 or 2). The trimming process includes forming a mask pattern that partially covers a top surface of the mold structure MS in a cell array region (see CAR of FIG. 1 or 2) and the contact region CCR, using the mask pattern to pattern the mold structure MS, reducing an area of the mask pattern, and using the reduced mask pattern to pattern the mold structure MS. Reducing the area of the mask pattern and using the reduced mask pattern to pattern the mold structure MS are performed alternately and repeatedly. The trimming process causes the mold structure MS to have a stepwise structure. As a result of the trimming process, a lowermost sacrificial layer SLb has a maximum length in the first direction D1, and an uppermost sacrificial layer SLa has a minimum length in the first direction D1.

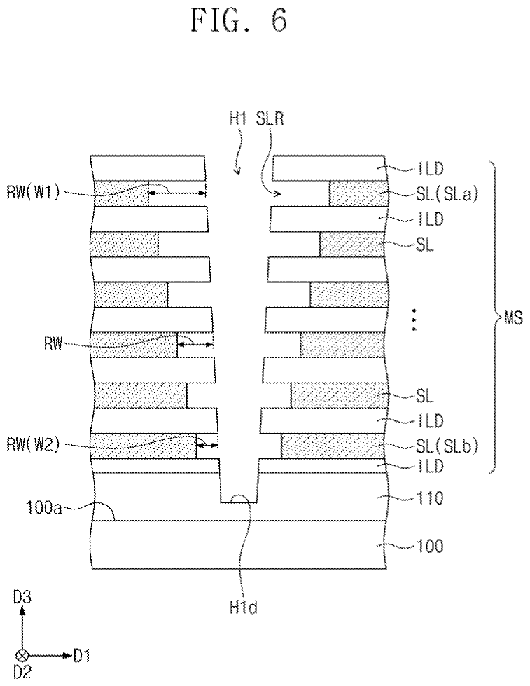

Referring to FIG. 6, in an embodiment, lateral surfaces of the sacrificial layers SL exposed by the first hole H1 are partially etched to form recesses SLR. The partial etching of the lateral surfaces of the sacrificial layers SL includes a wet etching process that uses an etching solution. The wet etching process etches portions of the lateral surfaces of the sacrificial layers SL, but does not etch the base dielectric layer 110 and the interlayer dielectric layers ILD.

The recesses SLR have widths RW in the horizontal direction, such as the first direction D1 or the second direction D2. The widths RW increase with increasing vertical distance from the substrate 100. For example, an uppermost recess SLR may have a width W1 greater than a width W2 of a lowermost recess SLR. Differences in width of the first hole H1 along the vertical direction D3 cause differences in widths RW of the recesses SLR along the vertical direction D3. In addition, a difference in an amount of etching in the vertical direction D3 also causes a difference in widths RW along the vertical direction D3. An amount of etching is relatively less at lower locations than at upper locations, and thus the recesses SLR are formed with smaller widths RW at lower locations.

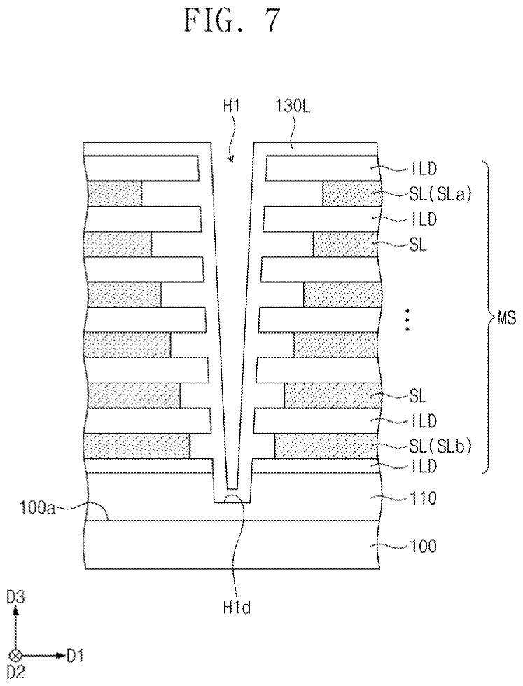

Referring to FIG. 7, in an embodiment, a buried storage layer 130L is formed that fills the recesses SLR and a portion of the first hole H1. The buried storage layer 130L is formed by using a film formation technique with excellent step coverage, such as chemical vapor deposition (CVD) or atomic layer deposition (ALD).

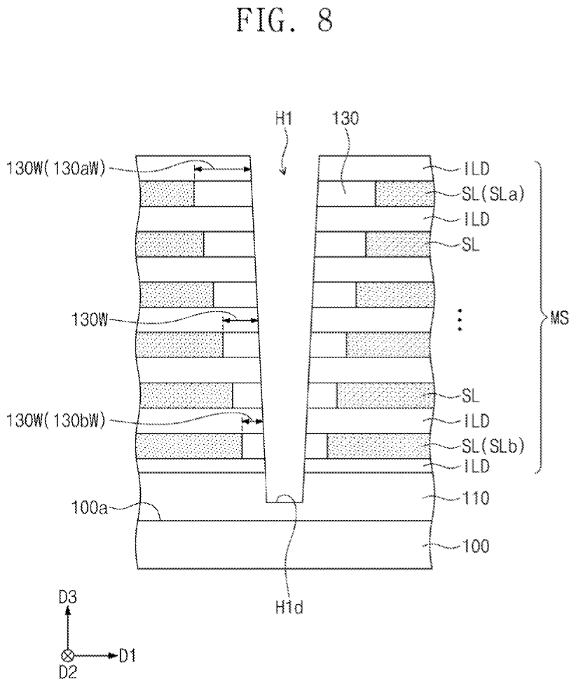

Referring to FIG. 8, in an embodiment, buried storage patterns 130 are formed. The formation of the buried storage patterns 130 is achieved by removing the buried storage layer 130L present within the first hole H1. An anisotropic etching process is performed that removes the buried storage layer 130L.

The buried storage patterns 130 have widths 130W in the horizontal direction, such as the first direction D1 or the second direction D2. The widths 130W increase with increasing vertical distance from the substrate 100. For example, a width 130aW of an uppermost buried storage pattern 130 may be greater than a width 130bW of a lowermost buried storage pattern 130. The difference in widths 130W of the buried storage patterns 130 is caused by the difference in widths RW in the horizontal direction, such as the first direction D1 or the second direction D2, of the recesses SLR described with reference to FIG. 6.

Referring back to FIGS. 2 and 3, in an embodiment, a bit line BL is formed that fills the first hole H1, the sacrificial layers SL are removed, and word lines WL are formed. The bit lines BL are formed by using a film formation technique such as chemical vapor deposition (CVD) or physical vapor deposition (PVD). A material for the bit lines BL is deposited, and then a planarization process is performed until a top surface of the stack structure ST is exposed. The planarization process includes, for example, one of a chemical mechanical polishing (CMP) process or an etch-back process.

In addition, the formation of the word lines WL includes forming a trench that penetrates the mold structure MS, where the trench exposes sidewalls of the sacrificial layers SL, forming empty regions by selectively removing the sacrificial layers SL through the exposed sidewalls of the sacrificial layers SL, and filling the empty regions with the word lines WL. The selective removal of the sacrificial layers SL includes a wet etching process that uses an etching solution. In conclusion, a stack structure ST can be formed that includes the word lines WL and the interlayer dielectric layers ILD.

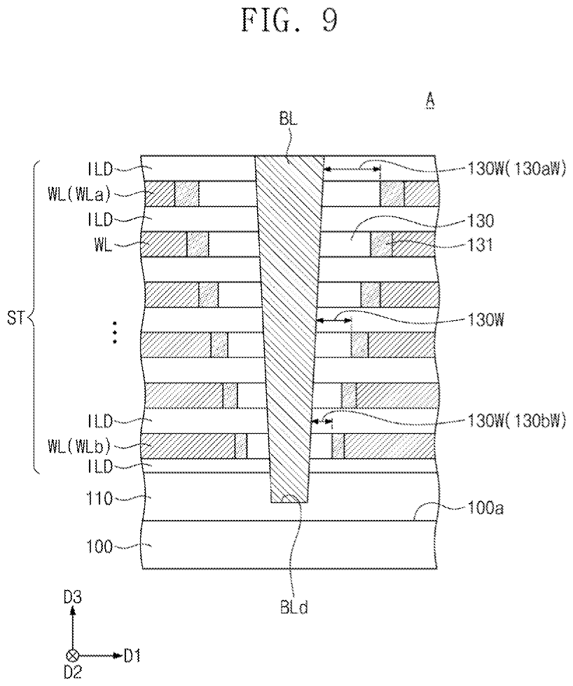

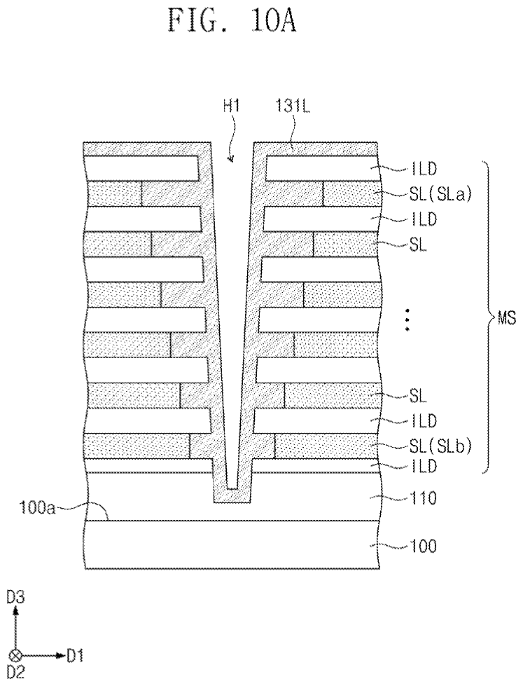

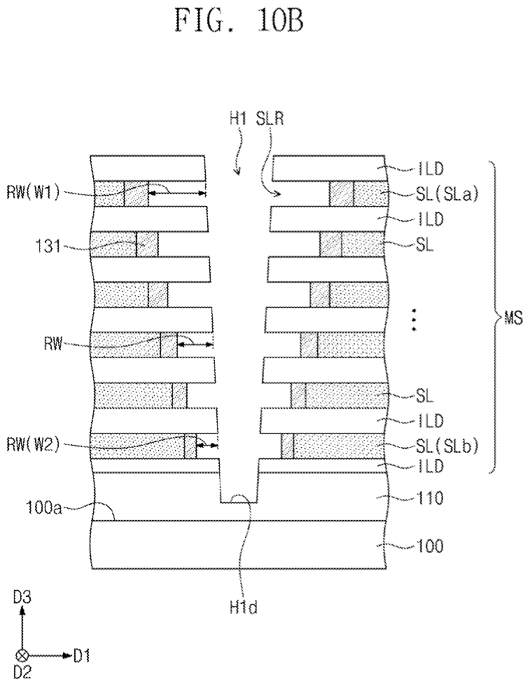

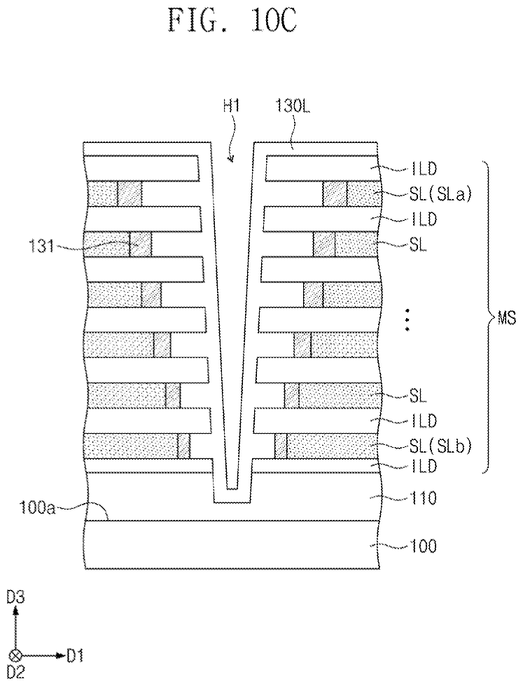

FIG. 9 is a cross-sectional view of a three-dimensional memory device according to some embodiments of the present inventive concepts. FIGS. 10A to 10C are cross-sectional views that illustrate a method of fabricating a three-dimensional memory device of FIG. 9. For brevity of description, differences in configuration will be principally described.

Referring to FIG. 9, in an embodiment, interlayer patterns 131 are correspondingly interposed between the buried storage patterns 130 and the word lines WL. The interlayer patterns 131 have shapes that surround outer lateral surfaces of corresponding buried storage patterns 130. The word lines WL are electrically connected through the interlayer patterns 131 to corresponding buried storage patterns 130. The interlayer patterns 131 include a conductive material. For example, the interlayer patterns 131 include carbon (C) or polycrystalline silicon (poly-Si). The interlayer patterns 131 prevent a material in the buried storage patterns 130 from diffusing into the word lines WL. Accordingly, a three-dimensional memory device is provided that has increased reliability and electrical properties.

Referring to FIG. 10A, in an embodiment, an interlayer 131L is formed. The interlayer 131L fills the recesses SLR described with reference to FIG. 6 and fills a portion of the first hole H1. The interlayer 131L is formed by using a film formation technique with excellent step coverage, such as chemical vapor deposition (CVD) or atomic layer deposition (ALD).

Referring to FIG. 10B, in an embodiment, interlayer patterns 131 are formed in the recesses SLR. The formation of the interlayer patterns 131 includes removing interlayer 131L portions adjacent to the first hole H1 from the recesses SLR and removing the interlayer 131L from the first hole H1. The removal of the interlayer 131L includes a wet etching process that uses an etching solution.

Referring to FIG. 10C, in an embodiment, a buried storage layer 130L is formed which fills unoccupied portions of the recesses SLR filled with the interlayer patterns 131 and also fills a portion of the first hole H1. The buried storage layer 130L is formed by using a film formation technique with excellent step coverage, such as chemical vapor deposition (CVD) or atomic layer deposition (ALD).

Referring back to FIG. 9, buried storage patterns 130, a bit line BL, and word lines WL are formed. The formation of the bit line BL and the word lines WL is substantially the same as that discussed with reference to FIGS. 2 and 3.

The buried storage patterns 130 are formed before forming the bit line BL and the word lines WL. The formation of the buried storage patterns 130 includes removing the buried storage layer 130L from the first hole H1. An anisotropic etching process is performed that removes the buried storage layer 130L.

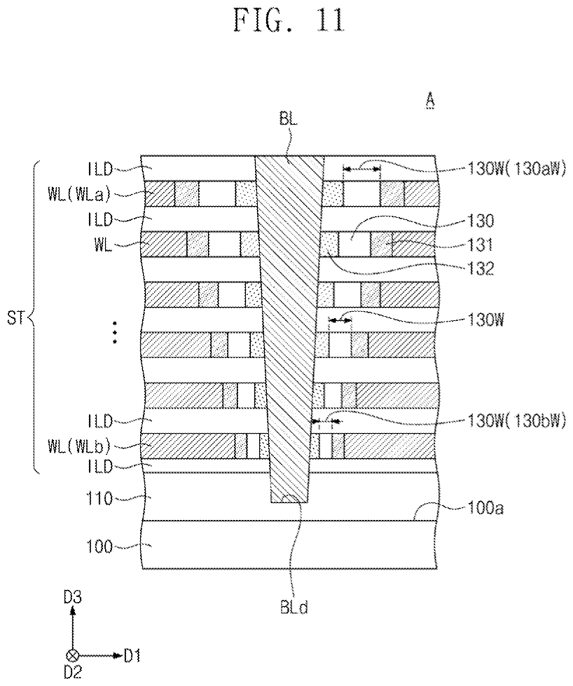

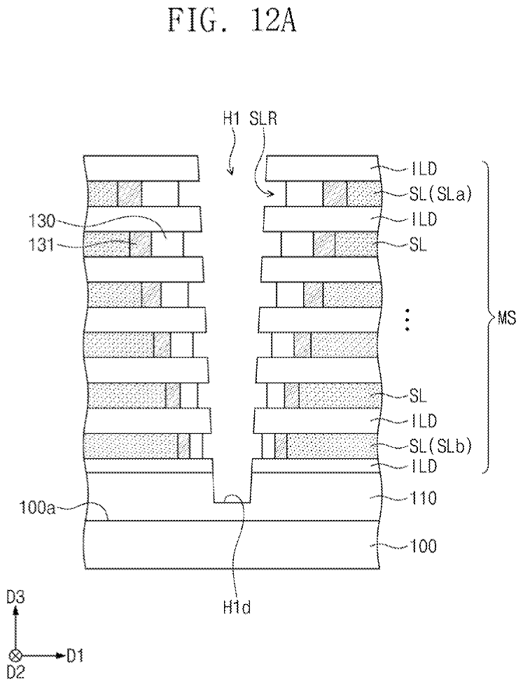

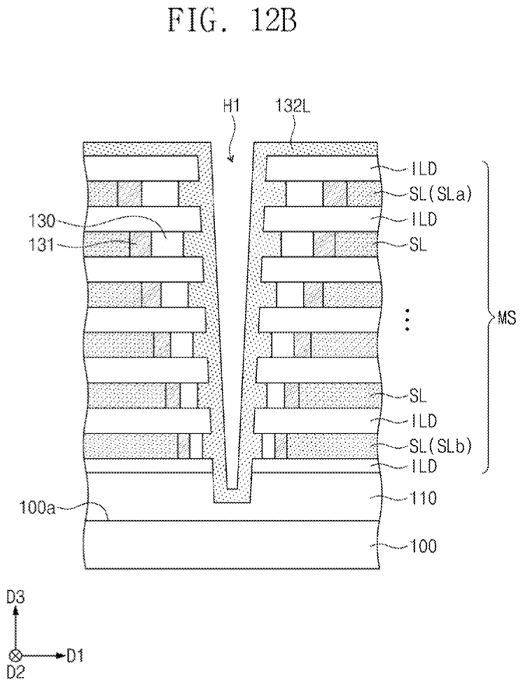

FIG. 11 is a cross-sectional view of a three-dimensional memory device according to some embodiments of the present inventive concepts. FIGS. 12A and 12B are cross-sectional views that illustrate a method of fabricating a three-dimensional memory device of FIG. 11. For brevity of description, differences in configuration will be principally described.

Referring to FIG. 11, in an embodiment, as described with reference to FIG. 9, interlayer patterns 131 are interposed between the buried storage patterns 130 and corresponding word lines WL. In addition, sub interlayer patterns 132 are interposed between corresponding buried storage patterns 130 and the bit line BL. The sub interlayer patterns 132 have annular shapes that surround the bit line BL. The buried storage patterns 130 are electrically connected through the sub interlayer patterns 132 to the bit line BL.

The sub interlayer patterns 132 include a conductive material. For example, the sub interlayer patterns 132 include carbon (C) or polycrystalline silicon (poly-Si). The sub interlayer patterns 132 prevent a material in the buried storage patterns 130 from diffusing into the bit line BL. Accordingly, a three-dimensional memory device with increased reliability and electrical properties is provided.

Referring to FIG. 12A, in an embodiment, interlayer patterns 131 and buried storage patterns 130 are formed in the recesses SLR. The forming of the interlayer patterns 131 is substantially the same as that described with reference to FIGS. 10A and 10B. The forming of the buried storage patterns 130 includes forming a buried storage layer that fills unoccupied portions of the recesses SLR filled with the interlayer patterns 131, and also fills a portion of the first hole H1, and removing the buried storage layer adjacent to the first hole H1 from the recesses SLR and removing the buried storage layer from the first hole H1. The removal of the buried storage layer includes a wet etching process that uses an etching solution.

Referring to FIG. 12B, in an embodiment, a sub interlayer 132L is formed that fills unoccupied portions of the recesses SLR filled with the interlayer patterns 131 and the buried storage patterns 130, and also fills a portion of the first hole H1. The sub interlayer 132L is formed by using a film formation technique with excellent step coverage, such as chemical vapor deposition (CVD) or atomic layer deposition (ALD).

Referring back to FIG. 11, in an embodiment, sub interlayer patterns 132, a bit line BL, and word lines WL are formed. The formation of the bit line BL and the word lines WL is substantially the same as that described with reference to FIGS. 2 and 3.

Sub interlayer patterns 132 are formed before the formation of the bit line BL and the word lines WL. The formation of the sub interlayer patterns 132 includes removing the sub interlayer 132L from the first hole H1. An anisotropic etching process is performed that removes the sub interlayer 132L.

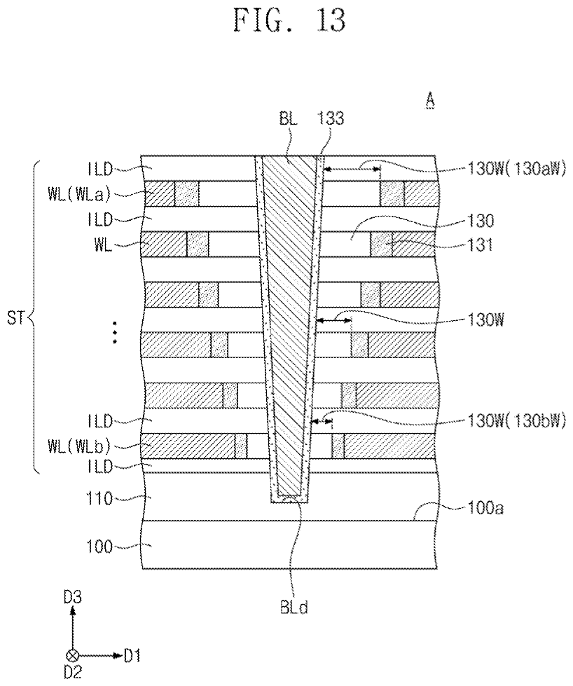

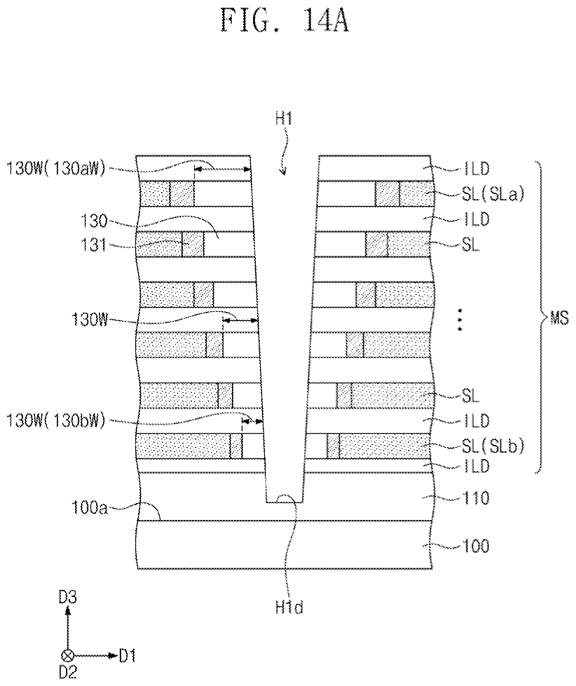

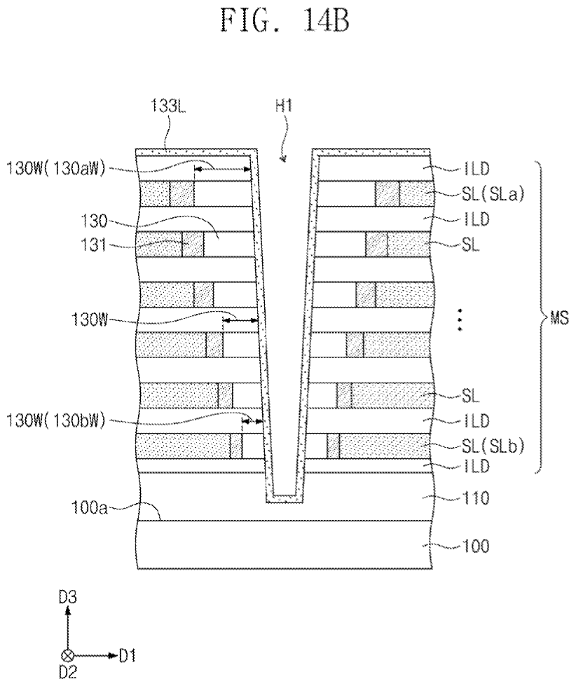

FIG. 13 is a cross-sectional view of a three-dimensional memory device according to some embodiments of the present inventive concepts. FIGS. 14A and 14B are cross-sectional views that illustrate a method of fabricating a three-dimensional memory device of FIG. 13. For brevity of description, differences in configuration will be principally described.

Referring to FIG. 13, in an embodiment, as discussed with reference to FIG. 9, interlayer patterns 131 are interposed between the buried storage patterns 130 and corresponding word lines WL. In addition, a line pattern 133 is disposed which extends in the vertical direction D3 between the bit line BL and the stack structure ST. The line pattern 133 surrounds the lateral surface of the bit line BL and extends to the bottom surface BLd of the bit line BL. The bit line BL is electrically connected through the line pattern 133 to the buried storage patterns 130. In addition, the bit line BL is electrically connected through the line pattern 133 to a circuit layer present in the base dielectric layer 110.

The line pattern 133 includes a conductive material. For example, the line pattern 133 includes carbon (C) or polycrystalline silicon (poly-Si). The line pattern 133 prevents a material in the buried storage patterns 130 from diffusing into the bit line BL. Accordingly, a three-dimensional memory device with increased reliability and electrical properties can be provided. Moreover, in comparison forming the interlayer patterns and sub interlayer patterns 131 and 132, forming the line pattern 133 has a reduced number of process steps.

Referring to FIG. 14A, in an embodiment, interlayer patterns 131 and buried storage patterns 130 are formed in the recesses SLR. The formation of the interlayer patterns 131 and the buried storage patterns 130 is substantially the same as that described with reference to FIGS. 9 to 10C.

Referring to FIG. 14B, in an embodiment, a first line layer 133L is formed that fills a portion of the first hole H1. The first line layer 133L extends onto the top surface of the mold structure MS. The first line layer 133L is formed by using a film formation technique with excellent step coverage, such as chemical vapor deposition (CVD) or atomic layer deposition (ALD).

Referring back to FIG. 13, in an embodiment, a line pattern 133, a bit line BL, and word lines WL are formed. The formation of the bit line BL and the word lines WL is substantially the same as that described with reference to FIGS. 2 and 3.

The line pattern 133 is formed before the formation of the bit line BL and the word lines WL. The formation of the line pattern 133 includes removing the first line layer 133L from the top surface of the mold structure MS. An etch-back process removes the first line layer 133L.

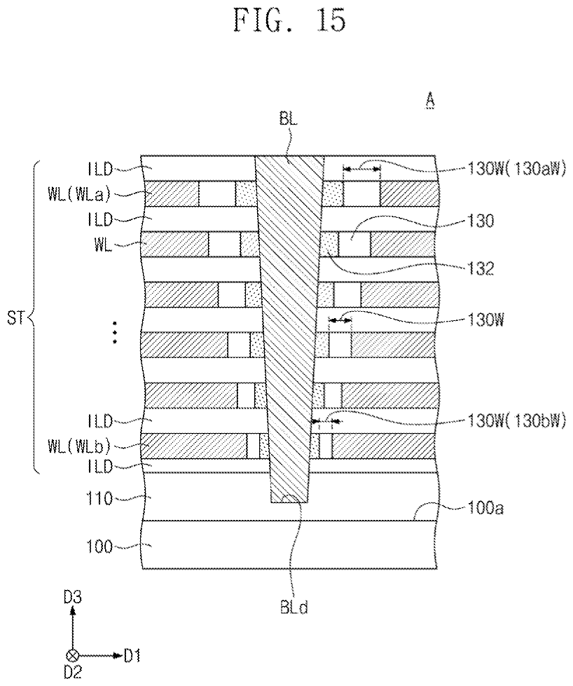

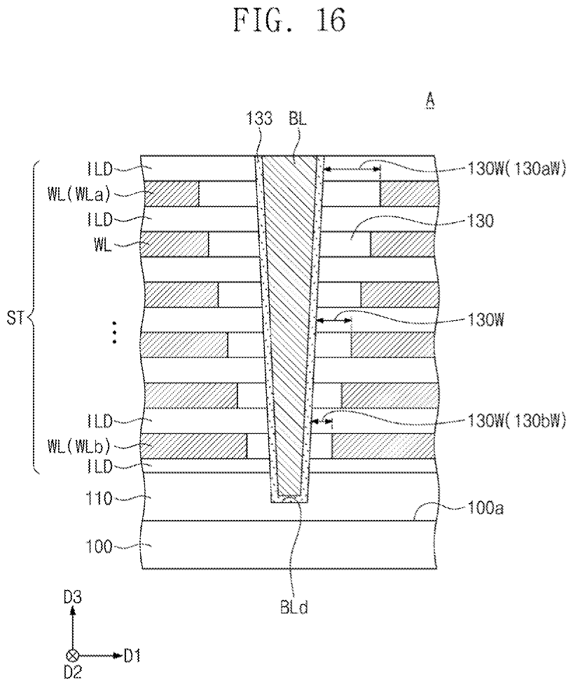

FIGS. 15 and 16 are cross-sectional views of a three-dimensional memory device according to some embodiments of the present inventive concepts. For brevity of description, differences in configuration will be principally described.

Referring to FIG. 15, in an embodiment, sub interlayer patterns 132 interposed between corresponding buried storage patterns 130 and the bit line BL. The sub interlayer patterns 132 have annular shapes that surround the bit line BL. The sub interlayer patterns 132 are substantially the same as the sub interlayer patterns 132 described with reference to FIG. 11. The formation of the sub interlayer patterns 132 is substantially the same as that described with reference to FIGS. 11 to 12B.

Referring to FIG. 16, in an embodiment, a line pattern 133 is disposed that extends in the vertical direction D3 between the bit line BL and the stack structure ST. The line pattern 133 is substantially the same as the line pattern 133 described with reference to FIG. 13. The formation of the line pattern 133 is substantially the same as that described with reference to FIGS. 13 to 14B.

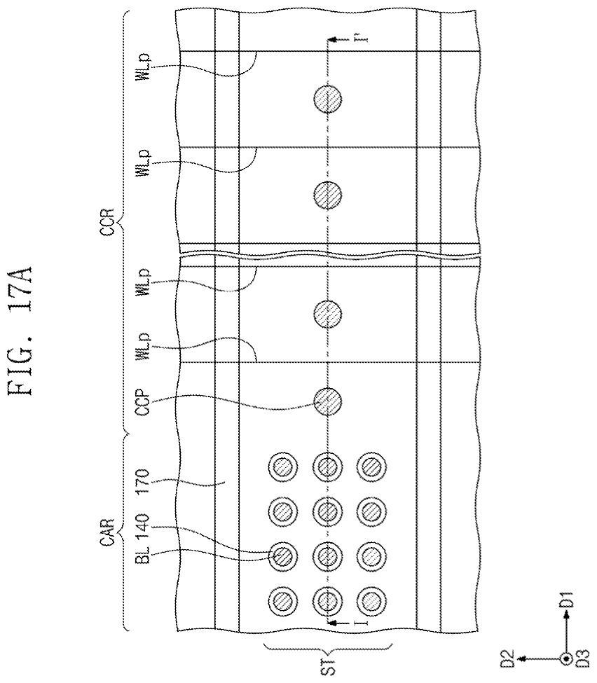

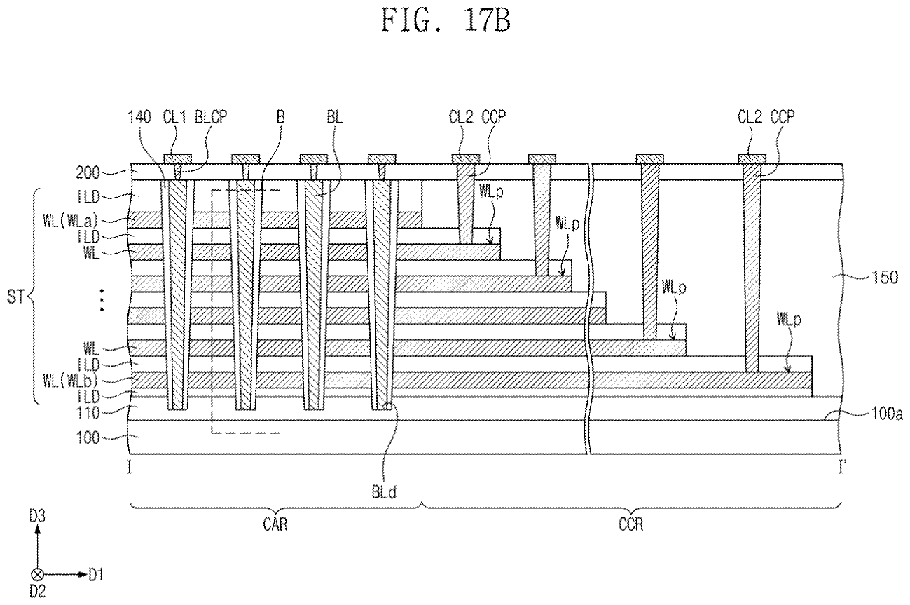

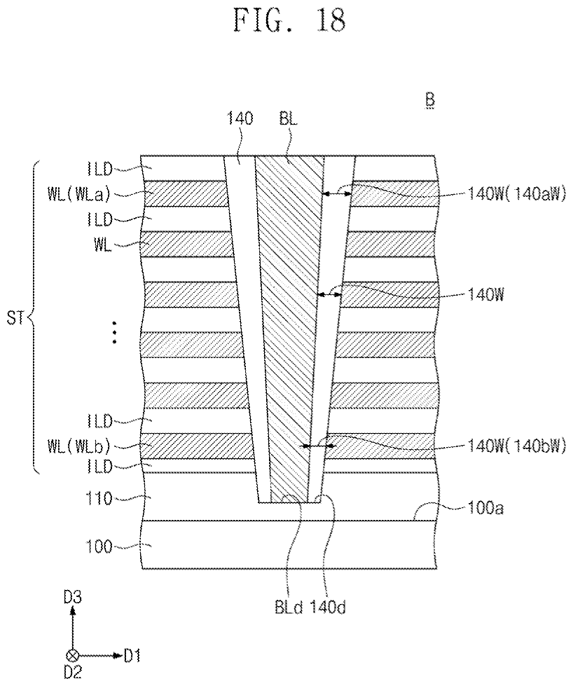

FIG. 17A is a plan view of a three-dimensional memory device according to some embodiments of the present inventive concepts. FIG. 17B is a cross-sectional view taken along line I-I′ of FIG. 17A of a three-dimensional memory device according to some embodiments of the present inventive concepts. FIG. 18 is an enlarged view of section B of FIG. 17B. For brevity of description, differences in configuration will be principally described.

Referring to FIGS. 17A and 17B, in an embodiment, a three-dimensional memory device includes a substrate 100, a base dielectric layer 110, a stack structure ST, a pad dielectric layer 150, bit lines BL, cell contact plugs CCP, an upper dielectric layer 200, bit-line contact plugs BLCP, and first and second conductive lines CL1 and CL2. The components mentioned above are substantially the same as those described with reference to FIGS. 1 and 2.

Referring to FIG. 18, in an embodiment, a line storage pattern 140 is disposed that extends in the vertical direction D3 between the bit line BL and the stack structure ST. The line storage pattern 140 surrounds the lateral surface of the bit line BL. The line storage pattern 140 has a width 140W in the horizontal direction, such as the first direction D1 or the second direction D2, parallel to the top surface 100a of the substrate 100. The width 140W of the line storage pattern 140 increases with increasing vertical distance from the substrate 100. A width 140aW at an uppermost portion of the line storage pattern 140 is greater than a width 140bW at a lower portion of the line storage pattern 140.

The line storage pattern 140 has a bottom surface 140d that causes the bottom surface BLd of the bit line BL to be exposed within the base dielectric layer 110. In addition, one or more stacked circuit layers are included in the base dielectric layer 110, and the bit lines BL are electrically connected to the circuit layers. Therefore, since the bottom surface BLd of the bit line BL is exposed without being covered by the line storage pattern 140, the bit line BL is electrically connected to the circuit layer in the base dielectric layer 110.

The line storage pattern 140 constitutes a plurality of memory cells. The plurality of memory cells are correspondingly distinguished by the word lines WL connected to the line storage pattern 140.

The line storage pattern 140 includes an Ovonic threshold switch (OTS) material, such as a chalcogenide-based material. For example, the line storage pattern 140 includes at least one of selenium (Se), tellurium (Te), arsenic (As), antimony (Sb), carbon (C), germanium (Ge), silicon (Si), or indium (In).

In comparison with a structure that includes the buried storage patterns 130, a three-dimensional memory device that includes the line storage pattern 140 has a simpler fabrication process. Accordingly, a manufacturing cost can be reduced and a process speed can be increased.

As discussed with reference to FIGS. 1 to 3, characteristics of a planar shape of the word line WL can cause a large parasitic capacitance. Further, a large parasitic capacitance may be produced at lower locations as compared to upper locations, and the device operating speed may be reduced at lower locations.

According to embodiments of the present inventive concepts, the line storage patterns 140 have different widths 140W along the vertical direction D3, and thus variations of operating characteristics between positions of a plurality of memory cells can be reduced. The line storage patterns 140 at lower locations intentionally have widths less than at upper locations, and thus there an operating voltage (Vth) is reduced at lower locations. Therefore, a reduction in operating speed caused by a large parasitic capacitance at lower locations can be suppressed and a variation in operating characteristics between positions of the plurality of memory cells can be reduced. Accordingly, a three-dimensional memory device has increased reliability.

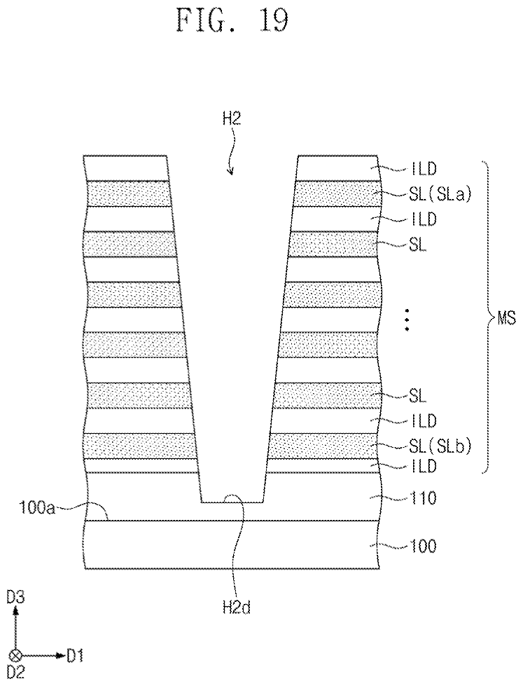

FIGS. 19 to 21 are cross-sectional views that illustrate a method of fabricating a three-dimensional memory device of FIG. 18. For brevity of description, differences in configuration will be principally described.

Referring to FIG. 19, in an embodiment, a base dielectric layer 110 is formed on a substrate 100. Sacrificial layers SL and interlayer dielectric layers ILD are alternately stacked and form a mold structure MS on the base dielectric layer 110. The base dielectric layer 110 and the interlayer dielectric layer ILD include, for example, silicon oxide. The sacrificial layers SL have an etch selectivity with respect to the base dielectric layer 110 and the interlayer dielectric layers ILD, and include silicon nitride. A second hole H2 is formed that penetrates the mold structure MS and a portion of the base dielectric layer 110. The second hole H2 has a width in the horizontal direction, such as the first direction D1 or the second direction D2, that increases with increasing vertical distance from the substrate 100. A plurality of second holes H2 are formed that are spaced apart from each other in the first direction D1. The second hole H2 has a bottom surface H2d positioned in the base dielectric layer 110. For example, the second hole H2 penetrates an upper portion of the base dielectric layer 110, but does not expose a top surface 100a of the substrate 100. An anisotropic etching process forms the second hole H2.

Before forming of the second hole H2, a trimming process is performed on the mold structure MS in a contact region (see CCR of FIG. 1 or 2). The trimming process includes forming a mask pattern that partially covers a top surface of the mold structure MS in a cell array region (see CAR of FIG. 1 or 2) and the contact region CCR, using the mask pattern to pattern the mold structure MS, reducing an area of the mask pattern, and using the reduced mask pattern to pattern the mold structure MS. Reducing the area of the mask pattern and using the reduced mask pattern to pattern the mold structure MS are performed alternately and repeatedly. The trimming process causes the mold structure MS to have a stepwise structure. As a result of the trimming process, a lowermost sacrificial layer SLb has a maximum length in the first direction D1, and an uppermost sacrificial layer SLa has a minimum length in the first direction D1.

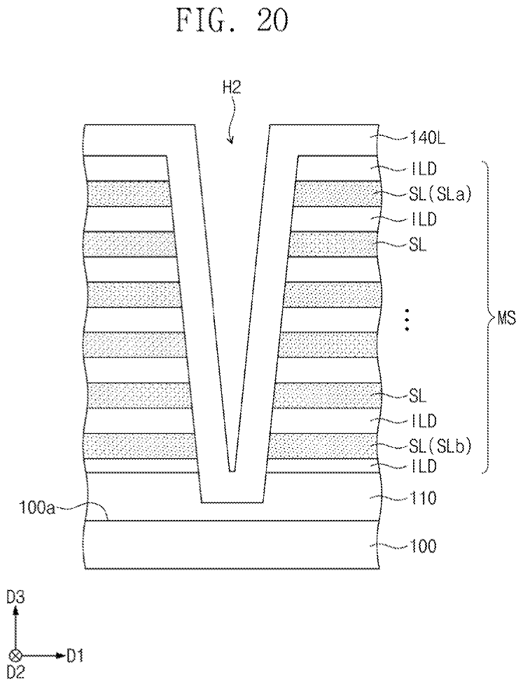

Referring to FIG. 20, in an embodiment, a line storage layer 140L is formed that fills a portion of the second hole H2. The line storage layer 140L by using a film formation technique with excellent step coverage, such as chemical vapor deposition (CVD) or atomic layer deposition (ALD). The line storage layer 140L extends onto the top surface of the mold structure MS.

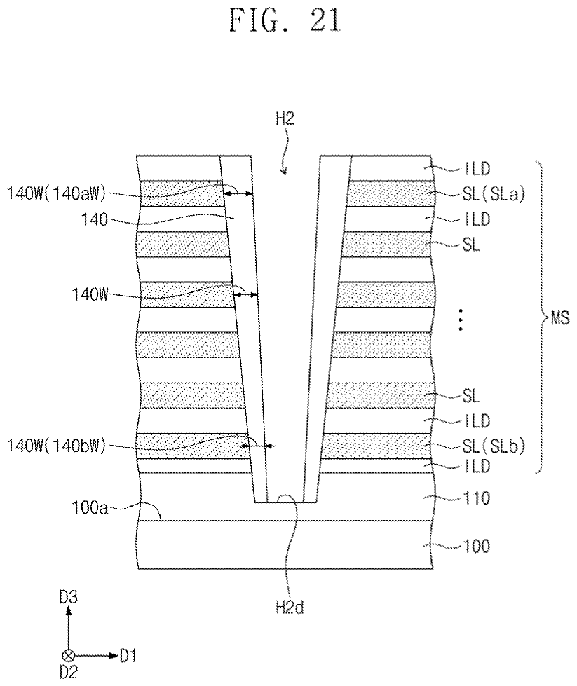

Referring to FIG. 21, in an embodiment, a line storage pattern 140 is formed. The formation of the line storage pattern 140 includes removing the line storage layer 140L from the top surface of the mold structure MS and removing the line storage layer 140L from a central portion of a bottom surface H2d of the second hole H2. An anisotropic etching process removes the line storage layer 140L. In the etching process that removes the line storage layer 140L, there is an increase in the amount of etching at lower locations as compared to upper locations. Therefore, a width 140W in the horizontal direction, such as the first direction D1 or the second direction D2, of the line storage pattern 140 increases with increasing vertical distance from the substrate 100. A width 140aW at an uppermost portion of the line storage pattern 140 is greater than a width 140bW at a lower portion of the line storage pattern 140. After forming the line storage pattern 140, the bottom surface H2d of the second hole H2 is partially exposed.

Referring back to FIGS. 17A and 17B, a bit line BL and word lines WL are formed. The formation of the bit line BL and the word lines WL is substantially the same as that described with reference to FIGS. 2 and 3.

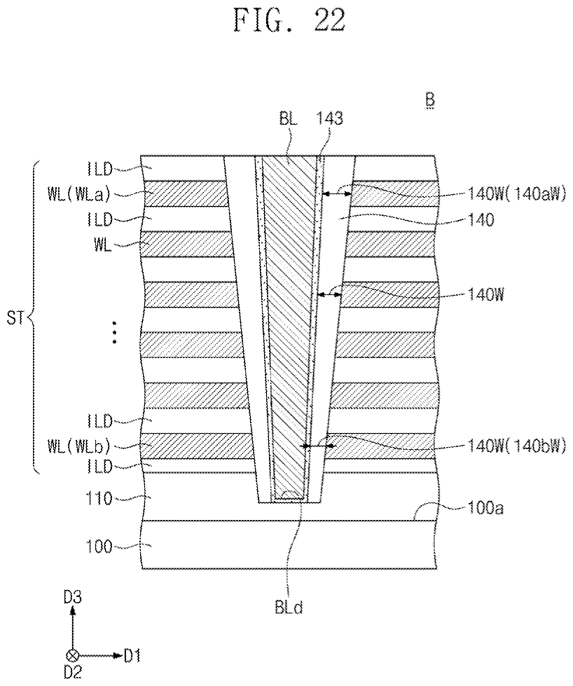

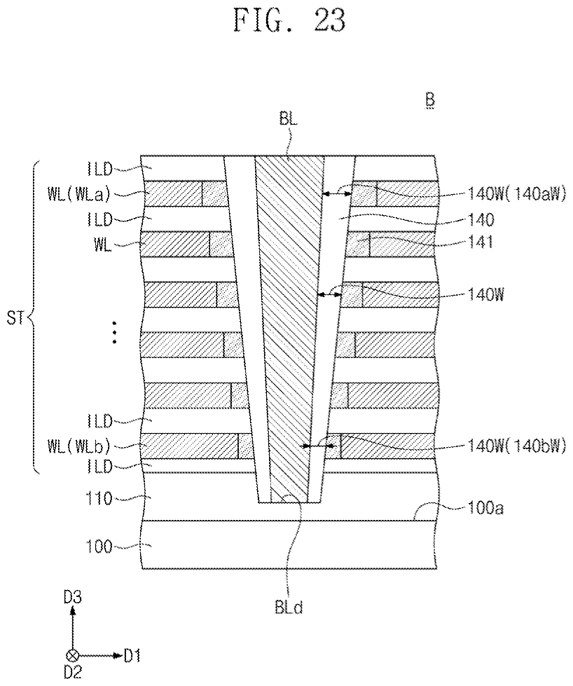

FIGS. 22 and 23 are cross-sectional views of a three-dimensional memory device according to some embodiments of the present inventive concepts. For brevity of description, differences in configuration will be principally described.

Referring to FIG. 22, in an embodiment, a sub line pattern 143 is interposed that extends in the vertical direction D3 between the bit line BL and the line storage pattern 140. The sub line pattern 143 surrounds the lateral surface of the bit line BL and extends to the bottom surface BLd of the bit line BL. The bit line BL is electrically connected through the sub line pattern 143 to the line storage pattern 140. In addition, the bit line BL is electrically connected through the sub line pattern 143 to a circuit layer present in the base dielectric layer 110.

The sub line pattern 143 includes a conductive material. For example, the sub line pattern 143 includes carbon (C) or polycrystalline silicon (poly-Si). The sub line pattern 143 prevents a material in the line storage patterns 140 from diffusing into the bit line BL. Accordingly, a three-dimensional memory device with increased reliability and electrical properties can be provided. Moreover, as compared with the formation of the interlayer patterns and sub interlayer patterns 131 and 132, the formation of the sub line pattern 143 uses fewer process steps.

The formation of the sub line pattern 143 is substantially the same as that described with reference to FIGS. 13 to 14B.

Referring to FIG. 23, in an embodiment, liner interlayer patterns 141 are interposed between the line storage pattern 140 and corresponding word lines WL. Each of the liner interlayer patterns 141 has an annular shape that surrounds an outer lateral surface of the line storage pattern 140. The word lines WL are electrically connected through the liner interlayer patterns 141 to the line storage pattern 140. The liner interlayer patterns 141 include a conductive material. For example, the liner interlayer patterns 141 include carbon (C) or polycrystalline silicon (poly-Si). The liner interlayer patterns 141 prevent a material in the line storage pattern 140 from diffusing into the word lines WL. Accordingly, a three-dimensional memory device with increased reliability and electrical properties can be provided.

The formation of the liner interlayer patterns 141 is substantially the same as that described with reference to FIGS. 9 to 10C.

In a three-dimensional memory device according to embodiments of the present inventive concepts, a storage pattern has a thickness that decreases in a direction from upper to lower locations, and thus deviations in operating speed between a plurality of memory cells can be reduced.

Although embodiments of the present inventive concepts have been described with reference to the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A three-dimensional memory device, comprising:
a base dielectric layer disposed on a substrate;
a stack structure that includes a plurality of word lines and a plurality of interlayer dielectric layers that are alternately stacked on the base dielectric layer;
a bit line that penetrates the stack structure and extends in a vertical direction perpendicular to a top surface of the substrate; and
a plurality of buried storage patterns interposed between the bit line and the word lines and spaced apart from each other in the vertical direction, wherein the buried storage patterns surround a lateral surface of the bit line,
wherein each of the buried storage patterns has a width in a horizontal direction parallel to the top surface of the substrate,
wherein the widths of the buried storage patterns increase with increasing vertical distance from the substrate.

2. The device of claim 1, wherein the buried storage patterns include at least one of selenium (Se), tellurium (Te), arsenic (As), antimony (Sb), carbon (C), germanium (Ge), silicon (Si), or indium (In).

3. The device of claim 1, further comprising a plurality of interlayer patterns that are disposed between the buried storage patterns and corresponding word lines.

4. The device of claim 3, further comprising a plurality of sub interlayer patterns that are disposed between corresponding buried storage patterns and the bit line.

5. The device of claim 3, further comprising a line pattern that extends in the vertical direction between the bit line and the stack structure and surrounds the lateral surface of the bit line.

6. The device of claim 1, further comprising a plurality of sub interlayer patterns that are disposed between corresponding buried storage patterns and the bit line.

7. The device of claim 1, further comprising a line pattern that extends in the vertical direction between the bit line and the stack structure and surrounds the lateral surface of the bit line.

8. A three-dimensional memory device, comprising:
a base dielectric layer disposed on a substrate;
a stack structure that includes a plurality of word lines and a plurality of interlayer dielectric layers that are alternately stacked on the base dielectric layer;
a bit line that penetrates the stack structure and extends in a vertical direction perpendicular to a top surface of the substrate; and
a line storage pattern that extends in the vertical direction between the bit line and the stack structure and surrounds a lateral surface of the bit line,
wherein the line storage pattern has a width in a horizontal direction parallel to the top surface of the substrate,
wherein the width of the line storage pattern increases with increasing vertical distance from the substrate.

9. The device of claim 8, wherein
a bottom surface of the bit line is located in the base dielectric layer, and
a bottom surface of the line storage pattern exposes the bottom surface of the bit line within the base dielectric layer.

10. The device of claim 8, further comprising a sub line pattern interposed between the bit line and the line storage pattern,
wherein the sub line pattern extends in the vertical direction and surrounds the lateral surface of the bit line.

11. A three-dimensional memory device, comprising:
a substrate that includes a cell array region and a contact region that extends from the cell array region;
a stack structure that includes a plurality of interlayer dielectric layers and a plurality of word lines that are alternately stacked on the substrate, wherein the stack structure includes a plurality of pad portions that have a stepwise structure on the contact region;
a pad dielectric layer that covers the pad portions of the stack structure on the contact region;
a plurality of bit lines that penetrate the stack structure on the cell array region and extend in a vertical direction perpendicular to a top surface of the substrate;
a plurality of buried storage patterns interposed between the word lines and each of the bit lines and spaced apart from each other in the vertical direction, wherein the buried storage patterns surround a lateral surface of each of the bit lines;
an upper dielectric layer that covers the stack structure; and
a plurality of cell contact plugs that penetrate the upper dielectric layer and the pad dielectric layer on the contact region and are connected to the word lines,
wherein the word lines have lengths in a first direction parallel to the top surface of the substrate, wherein the lengths decrease with increasing vertical distance from the top surface of the substrate,
wherein each of the buried storage patterns has a width in a horizontal direction parallel to the top surface of the substrate,
wherein the widths of the buried storage patterns increase with increasing vertical distance from the substrate.

12. The device of claim 11, wherein the buried storage patterns include at least one of selenium (Se), tellurium (Te), arsenic (As), antimony (Sb), carbon (C), germanium (Ge), silicon (Si), or indium (In).

13. The device of claim 11, further comprising a plurality of interlayer patterns that are interposed between the buried storage patterns and corresponding word lines.

14. The device of claim 13, further comprising a plurality of sub interlayer patterns that are interposed between corresponding buried storage patterns and the bit lines.

15. The device of claim 13, further comprising a plurality of line patterns that extend in the vertical direction between the stack structure and each of the bit lines and surround the lateral surface of each of the bit lines.

16. The device of claim 11, further comprising a plurality of sub interlayer patterns that are interposed between corresponding buried storage patterns and the bit lines.

17. The device of claim 11, further comprising a plurality of line patterns that extend in the vertical direction between the stack structure and each of the bit lines and surround the lateral surface of each of the bit lines.

18. The device of claim 17, wherein the line patterns include carbon (C).

19. A three-dimensional memory device, comprising:
a substrate that includes a cell array region and a contact region that extends from the cell array region;
a stack structure that includes a plurality of interlayer dielectric layers and a plurality of word lines that are alternately stacked on the substrate, wherein the stack structure includes a plurality of pad portions that have a stepwise structure on the contact region;
a pad dielectric layer that covers the pad portions of the stack structure on the contact region;
a plurality of bit lines that penetrate the stack structure on the cell array region and extend in a vertical direction perpendicular to a top surface of the substrate;
a plurality of line storage patterns that extend in the vertical direction between the stack structure and each of the bit lines and surround a lateral surface of each of the bit lines;
an upper dielectric layer that covers the stack structure; and
a plurality of cell contact plugs that penetrate the upper dielectric layer and the pad dielectric layer on the contact region and are connected to the word lines,
wherein the word lines have lengths in a first direction parallel to the top surface of the substrate, the lengths decrease with increasing vertical distance from the top surface of the substrate,
wherein the line storage patterns have widths in a horizontal direction parallel to the top surface of the substrate,
wherein the widths of the line storage patterns increase with increasing vertical distance from the substrate.

20. The device of claim 19, further comprising a plurality of sub line patterns interposed between the line storage patterns and each of the bit lines,
wherein the sub line patterns extend in the vertical direction and surround the lateral surface of each of the bit lines.
